(19) United States
(12) Patent Application Publication
(10) Pub. No.: US 2026/0141964 A1
(43) Pub. Date: May 21, 2026

(54) READ DISTURB TRACKING FOR DECKS OF A MEMORY BLOCK

(71) Applicant: Micron Technology, Inc., Boise, ID (US)

(72) Inventors: Hanping Chen, San Jose, CA (US); Murong Lang, San Jose, CA (US); Peng Zhang, Los Altos, CA (US)

(21) Appl. No.: 18/951,337

(22) Filed: Nov. 18, 2024

(51) Int. Cl. G11C 16/34; G11C 16/20; G11C 16/26

(52) U.S. Cl. CPC G11C 16/3431; G11C 16/20; G11C 16/26

(57) ABSTRACT

Exemplary methods, apparatuses, and systems including an operation tracker for tracking operations of decks of a memory block. The operation tracker receives a command for a deck of a memory. The memory includes a plurality of separately accessible decks partitioned from a physical block of the memory. The operation tracker increments a read count for a deck of the plurality of separately accessible decks. Responsive to determining that the read count for the deck of the plurality of separately accessible decks satisfies a read count threshold, the operation tracker triggers a read disturb scan of the deck.

### TECHNICAL FIELD

The present disclosure generally relates to read disturb tracking, and more specifically, relates to read disturb tracking for decks of a block.

### BACKGROUND ART

A memory subsystem can include one or more memory devices that store data. The memory devices can be, for example, non-volatile memory devices and volatile memory devices. In general, a host system can utilize a memory subsystem to store data at the memory devices and to retrieve data from the memory devices.

### BRIEF DESCRIPTION OF THE DRAWINGS

The disclosure will be understood more fully from the detailed description given below and from the accompanying drawings of various embodiments of the disclosure. The drawings, however, should not be taken to limit the disclosure to the specific embodiments, but are for explanation and understanding only.

FIG. 1 illustrates an example computing system that includes a memory subsystem in accordance with some embodiments of the present disclosure.

FIG. 2 illustrates an example 200 of tracking operations of decks of a memory block, in accordance with some embodiments of the present disclosure.

FIG. 3 is a flow diagram of an example method to track erase operations for read disturb tracking, in accordance with some embodiments of the present disclosure.

FIG. 4 is a flow diagram of an example method to track program verify or read operations for read disturb tracking, in accordance with some embodiments of the present disclosure.

FIG. 5 is a flow diagram of an example method to track memory operations for read disturb tracking, in accordance with some embodiments of the present disclosure.

FIG. 6 is a block diagram of an example computer system in which embodiments of the present disclosure may operate.

### DETAILED DESCRIPTION

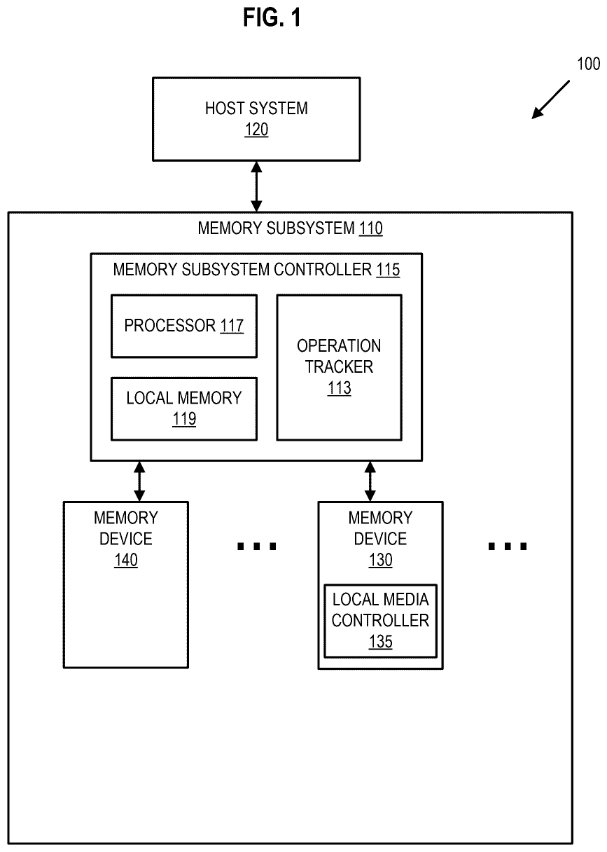

Aspects of the present disclosure are directed to read disturb tracking of decks from a block in a memory subsystem. A memory subsystem can be a storage device, a memory module, or a hybrid of a storage device and memory module. Examples of storage devices and memory modules are described below in conjunction with FIG. 1. In general, a host system can utilize a memory subsystem that includes one or more components, such as memory devices that store data. The host system can provide data to be stored at the memory subsystem and can request data to be retrieved from the memory subsystem.

A memory device can be a non-volatile memory device. A non-volatile memory device is a package of one or more dice. One example of non-volatile memory devices is a negative-and (NAND) memory device. Other examples of non-volatile memory devices are described below in conjunction with FIG. 1. The dice in the packages can be assigned to one or more channels for communicating with a memory subsystem controller. Each die can consist of one or more planes. Planes can be grouped into logic units (LUN). For some types of non-volatile memory devices (e.g., NAND memory devices), each plane consists of a set of physical blocks, which are groups of memory cells to store data. A cell is an electronic circuit that stores information.

Depending on the cell type, a cell can store one or more bits of binary information and has various logic states that correlate to the number of bits being stored. The logic states can be represented by binary values, such as “0” and “1”, or combinations of such values. There are various types of cells, such as single-level cells (SLCs), multi-level cells (MLCs), triple-level cells (TLCs), quad-level cells (QLCs), and penta-level cells (PLCs). For example, an SLC can store one bit of information and has two logic states while a QLC can store sixteen bits of information and has sixteen logic states.

Reliability is an example of a health indicator for a memory device. Reliability refers to the extent to which a memory device is capable of correctly reading data that has been previously written to the memory device. Reduced reliability of a memory device can result from a disturbance known as read disturb. A read disturb error occurs when a read operation on a portion of memory (e.g., cells of a first page of a block or a row or cells), often referred to as the aggressor, impacts the bias voltagebias voltages of unread memory cells in a different portion of memory (e.g., cells of a second page of the same block or a neighboring row of cells), often referred to as the victim. Memory devices typically have a finite tolerance for these disturbances. A sufficient amount of read disturb effects, such as a threshold number of read operations performed on aggressor cells, can change the victim cells in the other/unread portion of memory to different logical states than originally programmed, which results in read disturb errors.

Read disturb handling (RDH) is a process used to identify the risk of data loss caused by read disturb errors. When the risk of data loss (represented as a read bit error rate (RBER) for instance) of a portion of memory satisfies a threshold, the portion of memory is refreshed to mitigate the read disturb effects and reduce the risk of data loss. Refreshing the block includes re-reading and re-writing the data in the block to preserve the originally programmed states of the data. In conventional systems, RDH is triggered depending on a read count of the physical block. The read count for the physical block is measured by tracking a number of read commands used to access the physical block. When the read count of the physical block satisfies an RDH threshold (e.g., a threshold number of read counts), then RDH is triggered (e.g., a read disturb scan).

A block by deck (BBD) architecture is an architecture that partitions a single physical block into multiple logical blocks referred to as “decks.” The read stress of a deck in the BBD architecture is typically not shared across all decks of the physical block. As a result, read stress for a given deck can be underestimated or overestimated in conventional systems that trigger RDH according to the read count of the entire physical block. The underestimated read stresses in decks of the BBD architecture increase the risk of data loss. The overestimated read stresses in decks trigger unnecessary read disturb scans.

Aspects of the present disclosure address the above and other deficiencies by tracking the read stress for each deck in the BBD architecture. Tracking the read stress includes, e.g., tracking an operation count for each logical block partitioned from a physical block. Maintaining an accurate record of the read stress decreases the risk of data loss associated with each deck of a physical block by decreasing read disturb effects, latent read disturb effects, and read disturb induced charge loss. Additionally, maintaining an accurate record of read stress avoids unnecessarily triggering RDH handling, which reduces the unnecessary consumption of computing resources used during RDH.

FIG. 1 illustrates an example computing system 100 that includes a memory subsystem 110 in accordance with some embodiments of the present disclosure. The memory subsystem 110 can include media, such as one or more volatile memory devices (e.g., memory device 140), one or more non-volatile memory devices (e.g., memory device 130), or a combination of such.

A memory subsystem 110 can be a storage device, a memory module, or a hybrid of a storage device and memory module. Examples of a storage device include a solid-state drive (SSD), a flash drive, a universal serial bus (USB) flash drive, an embedded Multi-Media Controller (eMMC) drive, a Universal Flash Storage (UFS) drive, a secure digital (SD) card, and a hard disk drive (HDD). Examples of memory modules include a dual in-line memory module (DIMM), a small outline DIMM (SO-DIMM), and various types of non-volatile dual in-line memory module (NVDIMM).

The computing system 100 can be a computing device such as a desktop computer, laptop computer, network server, mobile device, a vehicle (e.g., airplane, drone, train, automobile, or other conveyance), Internet of Things (IoT) enabled device, embedded computer (e.g., one included in a vehicle, industrial equipment, or a networked commercial device), or such computing device that includes memory and a processing device.

The computing system 100 can include a host system 120 that is coupled to one or more memory subsystems 110. In some embodiments, the host system 120 is coupled to different types of memory subsystems 110. FIG. 1 illustrates one example of a host system 120 coupled to one memory subsystem 110. As used herein, “coupled to” or “coupled with” generally refers to a connection between components, which can be an indirect communicative connection or direct communicative connection (e.g., without intervening components), whether wired or wireless, including connections such as electrical, optical, magnetic, etc.

The host system 120 can include a processor chipset and a software stack executed by the processor chipset. The processor chipset can include one or more cores, one or more caches, a memory controller (e.g., NVDIMM controller), and a storage protocol controller (e.g., PCIe controller, SATA controller). The host system 120 uses the memory subsystem 110, for example, to write data to the memory subsystem 110 and read data from the memory subsystem 110.

The host system 120 can be coupled to the memory subsystem 110 via a physical host interface. Examples of a physical host interface include, but are not limited to, a serial advanced technology attachment (SATA) interface, a peripheral component interconnect express (PCIe) interface, universal serial bus (USB) interface, Fibre Channel, Serial Attached SCSI (SAS), Small Computer System Interface (SCSI), a double data rate (DDR) memory bus, a dual in-line memory module (DIMM) interface (e.g., DIMM socket interface that supports Double Data Rate (DDR)), Open NAND Flash Interface (ONFI), Double Data Rate (DDR), Low Power Double Data Rate (LPDDR), or any other interface. The physical host interface can be used to transmit data between the host system 120 and the memory subsystem 110. The host system 120 can further utilize an NVM Express (NVMe) interface to access components (e.g., memory devices 130) when the memory subsystem 110 is coupled with the host system 120 by the PCIe interface. The physical host interface can provide an interface for passing control, address, data, and other signals between the memory subsystem 110 and the host system 120. FIG. 1 illustrates a memory subsystem 110 as an example. In general, the host system 120 can access multiple memory subsystems via a same communication connection, multiple separate communication connections, and/or a combination of communication connections.

The memory devices 130,140 can include any combination of the different types of non-volatile memory devices and/or volatile memory devices. The volatile memory devices (e.g., memory device 140) can be, but are not limited to, random access memory (RAM), such as dynamic random access memory (DRAM) and synchronous dynamic random access memory (SDRAM).

Some examples of non-volatile memory devices (e.g., memory device 130) include negative-and (NAND) type flash memory and write-in-place memory, such as a three-dimensional cross-point (“3D cross-point”) memory device, which is a cross-point array of non-volatile memory cells. A cross-point array of non-volatile memory can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased. NAND type flash memory includes, for example, two-dimensional NAND (2D NAND) and three-dimensional NAND (3D NAND).

Although non-volatile memory devices such as NAND type memory (e.g., 2D NAND, 3D NAND) and 3D cross-point array of non-volatile memory cells are described, the memory device 130 can be based on any other type of non-volatile memory, such as read-only memory (ROM), phase change memory (PCM), self-selecting memory, other chalcogenide based memories, ferroelectric transistor random-access memory (FeTRAM), ferroelectric random access memory (FeRAM), magneto random access memory (MRAM), Spin Transfer Torque (STT)-MRAM, conductive bridging RAM (CBRAM), resistive random access memory (RRAM), oxide based RRAM (OxRAM), negative-or (NOR) flash memory, and electrically erasable programmable read-only memory (EEPROM).

A memory subsystem controller 115 (or controller 115 for simplicity) can communicate with the memory devices 130 to perform operations such as reading data, writing data, or erasing data at the memory devices 130 and other such operations (e.g., in response to commands scheduled on a command bus by controller 115). The memory subsystem controller 115 can include hardware such as one or more integrated circuits and/or discrete components, a buffer memory, or a combination thereof. The hardware can include digital circuitry with dedicated (i.e., hard-coded) logic to perform the operations described herein. The memory subsystem controller 115 can be a microcontroller, special purpose logic circuitry (e.g., a field programmable gate array (FPGA), an application specific integrated circuit (ASIC), etc.), or another suitable processor.

The memory subsystem controller 115 can include a processing device 117 (processor) configured to execute instructions stored in a local memory 119. In the illustrated example, the local memory 119 of the memory subsystem controller 115 includes an embedded memory configured to store instructions for performing various processes, operations, logic flows, and routines that control operation of the memory subsystem 110, including handling communications between the memory subsystem 110 and the host system 120.

In some embodiments, the local memory 119 can include memory registers storing memory pointers, fetched data, etc. The local memory 119 can also include read-only memory (ROM) for storing micro-code. While the example memory subsystem 110 in FIG. 1 has been illustrated as including the memory subsystem controller 115, in another embodiment of the present disclosure, a memory subsystem 110 does not include a memory subsystem controller 115, and can instead rely upon external control (e.g., provided by an external host, or by a processor or controller separate from the memory subsystem 110).

In general, the memory subsystem controller 115 can receive commands or operations from the host system 120 and can convert the commands or operations into instructions or appropriate commands to achieve the desired access to the memory device 130 and/or the memory device 140. The memory subsystem controller 115 can be responsible for other operations such as wear leveling operations, garbage collection operations, error detection and error-correcting code (ECC) operations, encryption operations, caching operations, and address translations between a logical address (e.g., logical block address (LBA), namespace) and a physical address (e.g., physical block address) that are associated with the memory devices 130. The memory subsystem controller 115 can further include host interface circuitry to communicate with the host system 120 via the physical host interface. The host interface circuitry can convert the commands received from the host system into command instructions to access the memory devices 130 and/or the memory device 140 as well as convert responses associated with the memory devices 130 and/or the memory device 140 into information for the host system 120.

The memory subsystem 110 can also include additional circuitry or components that are not illustrated. In some embodiments, the memory subsystem 110 can include a cache or buffer (e.g., DRAM) and address circuitry (e.g., a row decoder and a column decoder) that can receive an address from the memory subsystem controller 115 and decode the address to access the memory devices 130.

In some embodiments, the memory devices 130 include local media controllers 135 that operate in conjunction with memory subsystem controller 115 to execute operations on one or more memory cells of the memory devices 130. An external controller (e.g., memory subsystem controller 115) can externally manage the memory device 130 (e.g., perform media management operations on the memory device 130). In some embodiments, a memory device 130 is a managed memory device, which is a raw memory device combined with a local controller (e.g., local controller 135) for media management within the same memory device package. An example of a managed memory device is a managed NAND (MNAND) device.

The memory subsystem 110 includes an operation tracker 113 that can track memory operations for read disturb tracking. In some embodiments, the controller 115 includes at least a portion of the operation tracker 113. For example, the controller 115 can include a processor 117 (processing device) configured to execute instructions stored in local memory 119 for performing the operations described herein. In some embodiments, an operation tracker 113 is part of the host system 120, an application, or an operating system.

The operation tracker 113 can track a read count for decks of a block. The read counts that are tracked can be triggered responsive to receiving memory operations, including erase operations, program verify operations, and read operations. Further details regarding the operations of the operation tracker 113 are described below.

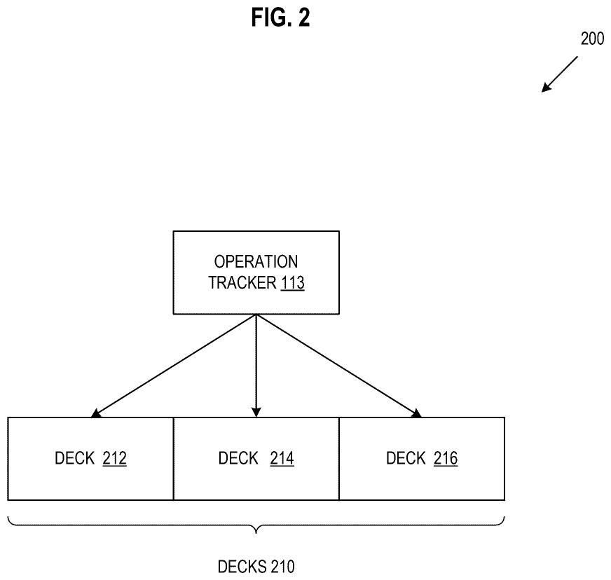

FIG. 2 illustrates an example 200 of tracking operations of decks of a memory block, in accordance with some embodiments of the present disclosure. In example 200, the operation tracker tracks operations (such as read operations, program verify operations, and erase operations) for deck 212, deck 214, and deck 216 respectively, collectively referred to herein as decks 210. As described herein, a BBD includes a number of decks (such as deck 212, deck 214, and deck 216) partitioned from a physical block of memory. For example, a physical block of memory can be divided vertically into decks 210 such that decks 210 share word lines of the physical block and divide bit lines of the physical block. Because decks 210 share a common characteristic (e.g., word lines), the read stress determined for an aggressor deck of the decks 210 (e.g., a deck being operated on, such as deck 214 for example) should be tracked with respect to the remaining decks of the deck 210 (e.g., victim decks, such as decks 212 and 216 for example).

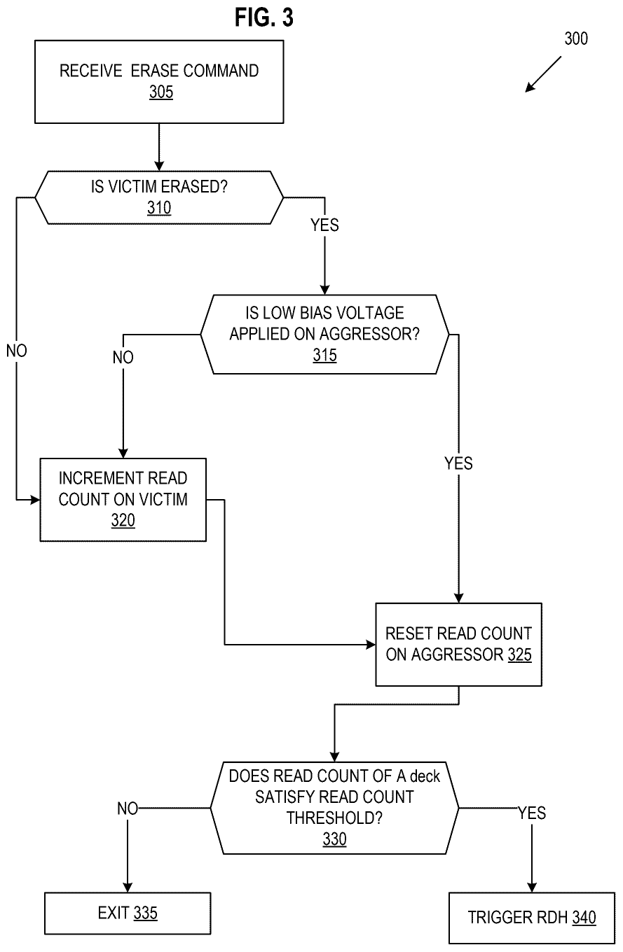

FIG. 3 is a flow diagram of an example method 300 to track erase operations for read disturb tracking, in accordance with some embodiments of the present disclosure. The method 300 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 500 is performed by the operation tracker 113 of FIG. 1. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At operation 305, the processing device receives an erase command. For example, the operation tracker 113 detects an erase operation being performed on a deck of a block. In general, an erase operation includes applying a negative voltage to a deck (or the block). The erase operation can be performed on the entire block, thereby erasing each deck. Additionally or alternatively, the erase operation can be performed on one or more decks of the block (e.g., “operated blocks”, where the operated blocks are referred to herein as aggressor blocks), and any remaining decks of the block are referred to herein as victim blocks. The operation tracker 113 triggers method 300 at operation 305 responsive to identifying (e.g., receiving the operation, detecting the operation, or the like) an erase operation performed on any deck of the block.

At operation 310, the processing device determines whether a victim deck is erased (e.g., the victim deck is in an erased state). For example, the operation tracker 113 can maintain a map of erased decks, indicating which decks are in an erased state. A victim deck is in an erased state if one or more operations received at a time before the erase operation received at operation 305 erased the victim deck. If a victim deck is in an erased state, then the flow of operations moves to operation 315. If the victim deck has is not in an erased state, then the flow of operations moves to operation 320.

At operation 315, the processing device determines whether a low bias voltage is applied to an aggressor deck. Voltages applied to decks can predetermined such that particular voltages satisfy particular charge levels, resulting in the reading, writing, or erasing of bits of the memory cell. The low bias voltage can be a low voltage (such as 1 volt) from the set of predetermined voltages used to read, write, and/or erase bits of the memory cell. If the voltage applied to the aggressor deck is a low bias voltage, then the flow of operations moves to operation 325. If the voltage applied to the aggressor deck is not a low bias voltage, then the flow of operations moves to operation 320.

At operation 320, the processing device increments a read count for a victim deck of the block. The operation tracker 113 increments a read count for each victim-deck. While referred to herein as a “read count,” the counter is tracking disturbance resulting from various operations, including program and erase operations (i.e., not just read operations). The operation tracker 113 accounts for the read stress of a victim deck except when the victim deck is erased with a low voltage threshold being applied to an aggressor deck. That is, the voltage applied to the aggressor deck is sufficiently low such that it does not cause read disturb stress on the victim decks.

At operation 325, the processing device resets the read count on the aggressor (e.g., the deck subject to the applied erase operation). For example, the operation tracker 113 sets the value of a read count associated with the aggressor deck to “0.”

At operation 330, the processing device determines whether the read count of a deck of a block satisfies a read count threshold. In operation, the operation tracker 113 maintains a read count for each deck of the block. The operation tracker 113 compares a value of a read count of any deck of the block to a threshold count value. If the value of the read count for a deck satisfies a threshold count value, then the flow of operations moves to operation 340. If the value of the count for a deck does not satisfy the threshold count value, then the flow of operations moves to operation 335.

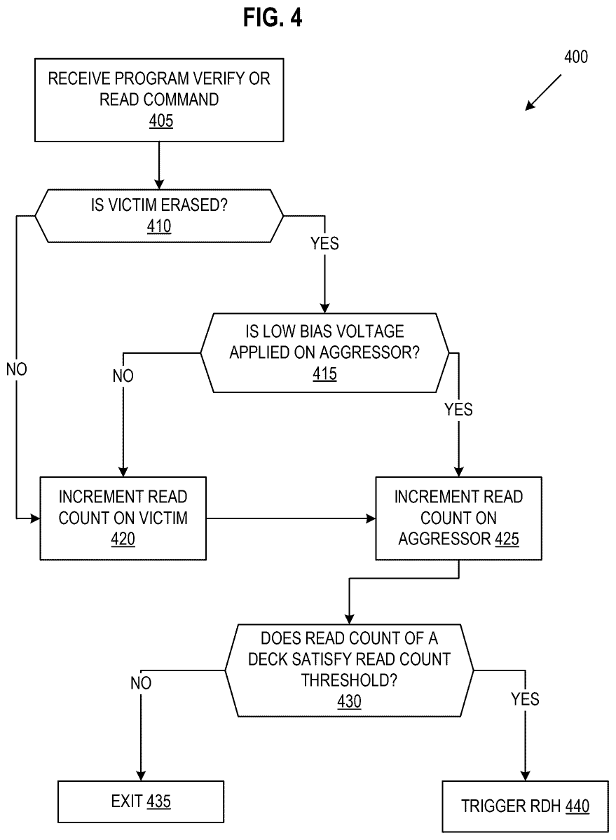

At operation 335, the method 300 terminates. For example, the operation tracker 113 monitors the next operation to determine whether to trigger method 300 or other methods such as method 400 described in FIG. 4.

At operation 340, the processing device triggers RDH for a particular deck that satisfied the read count threshold. As described herein, RDH is a process used to identify the risk of data loss caused by read disturb errors. The risk of data loss of a deck can be represented by a RBER, where a high RBER represents an increased risk of data loss and a low RBER represents a decreased risk of data loss. For example, the operation tracker 113 reads one or more codewords from the deck by applying a charge to the deck. The operation tracker 113 determines the RBER (or other error metric) of the codeword read from the deck. The operation tracker 113 can perform any one or more error correcting code (ECC) operations to determine the RBER of the codeword read from the deck. For example, the codeword is encoded data that was written to the word line using redundant ECC data (e.g., parity bits). The operation tracker 113 decodes the codeword (e.g., with an ECC decoder) to obtain stored data. The redundant data is leveraged to correct any changes relative to the data as it was intended to be stored. The number of bit changes is used to determine the RBER. If the RBER satisfies a threshold, the stored data is rewritten to memory.

FIG. 4 is a flow diagram of an example method 400 to track program verify or read operations for read disturb tracking, in accordance with some embodiments of the present disclosure. The method 400 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 500 is performed by the operation tracker 113 of FIG. 1. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At operation 405, the processing device receives a program verify command or a read command. For example, the operation tracker 113 detects a program verify operation or a read operation being performed on a deck of a block. In general, a read operation involves applying a voltage to a word line powering a transistor (e.g., a memory cell being operated on of a deck). The deck and/or block uses word lines and bit lines to access memory cells of the deck. By applying a charge to the word line, the transistor gate opens, allowing any stored charge of the transistor to flow to a decoder to decode the charge, mapping the charge to a bit value. For example, a memory cell can represent different bit values through the application of different bias voltage values to the transistor gate. A program verify operation is an operation used to verify the correct programming of word lines. For example, a write command can include a program verify operation. During a write command, a processing device applies an increasing sequence of voltage pulses to a word line of a deck (e.g., the aggressor deck). The program verify operation includes reading the voltage of each voltage pulse in the increasing sequence of voltage pulses of the aggressor deck. As a result of the voltage sensing, each verification of a voltage pulse is a read event that applies read stress to victim decks (e.g., remaining decks of the block that are not being operated on via the program verify operation applied to the aggressor deck). The operation tracker 113 triggers method 400 at operation 405 responsive to identifying a program verify operation or a read operation performed on any deck of the block.

Operations 410-420 are similar to the description above with reference to operations 310-320 of FIG. 3. For example, at operation 410, the processing device determines whether the victim deck is erased using a map indicating victim decks in an erased state. If a victim deck is in an erased state, then the flow of operations moves to operation 415. If the victim deck is not in an erased state, then the flow of operations moves to operation 420.

At operation 415, the processing device determines whether a low bias voltage is applied to the aggressor deck. The low bias voltage can be a low voltage (such as 1 volt) from a set of predetermined voltages used to read, write, and/or erase bits of the memory cell. If the voltage applied to the aggressor deck is a low bias voltage, then the flow of operations moves to operation 425. If the voltage applied to the aggressor deck is not a low bias voltage, then the flow of operations moves to operation 420.

At operation 420, the processing device increments a read count associated with each victim deck of the block. If the operation identified at operation 405 is a program verity operation, then the operation tracker 113 increments the count for each victim deck according to the number of verify operations of the program verify operation. As a result, a single program verify operation applied to an aggressor deck can increment a read count for each victim deck forty times, for example.

At operation 425, the processing device increments the read count for the aggressor deck, where the aggressor deck is the deck subject to the read operation or the program verify operation.

Operations 430-440 are similar to the description above with reference to operations 330-340 of FIG. 3. For example, at operation 430, the operation tracker 113 evaluates a read count for each deck of the block (e.g., including the value of the read count of the aggressor deck and the victim decks). If the value of the read count for a deck satisfies a threshold count value, then the flow of operations moves to operation 440. If the value of the read count for a deck does not satisfy the threshold count value, then the flow of operations moves to operation 435.

At operation 435, the method 400 terminates. For example, the operation tracker 113 monitors the next operation to determine whether to trigger method 400 or other methods such as method 300 described in FIG. 3.

At operation 440, the processing device triggers RDH. Responsive to determining that a read count of a deck satisfied a read count threshold, the operation tracker 113 determines the risk of data loss for that deck using RDH, where an RBER is calculated and represents the risk of data loss for that deck.

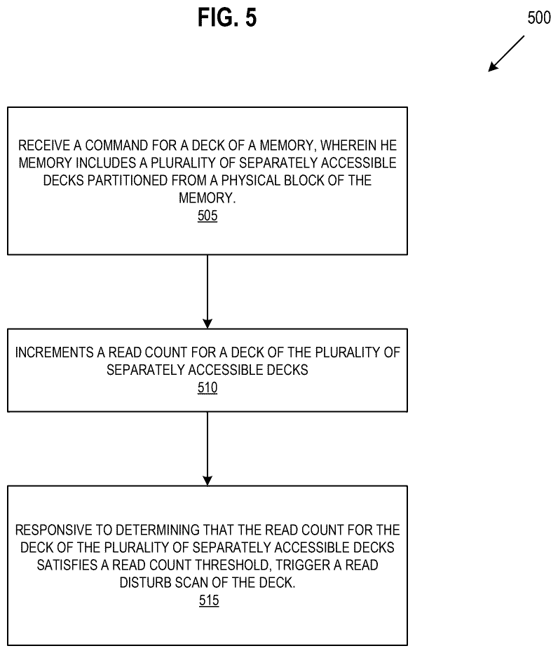

FIG. 5 is a flow diagram of an example method 500 to track memory operations for read disturb tracking, in accordance with some embodiments of the present disclosure. The method 500 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 500 is performed by the operation tracker 113 of FIG. 1. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At operation 505, the processing device receives a command for a deck of a memory. As described with reference to operation 305 of FIG. 3, the received command can include an erase command. As described with reference to operation 405 of FIG. 4, the received command can include a read command or a program verify command. The memory includes a plurality of separately accessible decks partitioned from a physical block of the memory. For example, as described with reference to FIG. 2, each of the decks share a word line, a bit line, or some other characteristic of a physical block by virtue of being partitioned from the physical block.

At operation 510, the processing device increments a read count for a deck of the plurality of separately accessible decks. As described with reference to either operation 320 of FIG. 3 or operation 420 of FIG. 4, the operation tracker 113 increments a read count on a victim deck (e.g., a deck that is not subject to the received operation) in response to the victim block not being identified as an erased victim block or in response to the victim block being identified as an erased victim block and a low bias voltage is not applied to the aggressor deck (e.g., the deck that is the subject to the received operation). As described with reference to operation 425 of FIG. 4, the operation tracker 113 increments a read count on the aggressor deck if the received operation is a program verify operation or a read operation.

At operation 515, responsive to determining that the read count for the deck of the plurality of separately accessible decks satisfies a read count threshold, the processing device triggers a read disturb scan of the deck. As described with reference to either operation 330 of FIG. 3 or operation 430 of FIG. 4, the operation tracker 113 evaluates a read count for each deck of the block (e.g., including the value of the read count of the aggressor deck and the victim decks). For example, the operation tracker 113 maintains a read count for each deck of a block. If the value of the read count for a deck satisfies a threshold count value, then the operation tracker 113 triggers RDH.

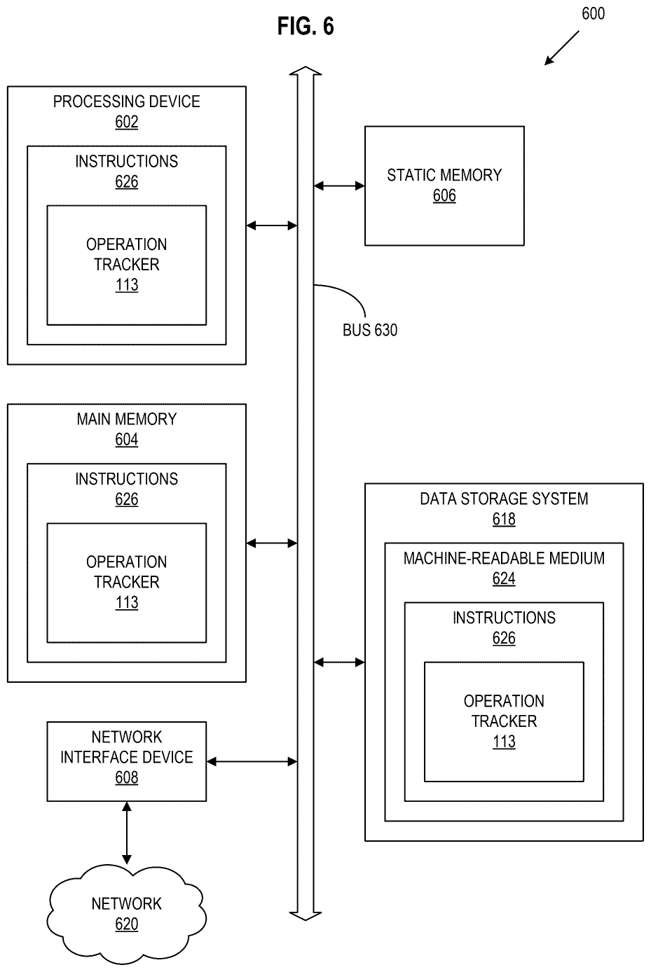

FIG. 6 illustrates an example machine of a computer system 600 within which a set of instructions, for causing the machine to perform any one or more of the methodologies discussed herein, can be executed. In some embodiments, the computer system 600 can correspond to a host system (e.g., the host system 120 of FIG. 1) that includes, is coupled to, or utilizes a memory subsystem (e.g., the memory subsystem 110 of FIG. 1) or can be used to perform the operations of a controller (e.g., to execute an operating system to perform operations corresponding to the operation tracker 113 of FIG. 1). In alternative embodiments, the machine can be connected (e.g., networked) to other machines in a LAN, an intranet, an extranet, and/or the Internet. The machine can operate in the capacity of a server or a client machine in client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 600 includes a processing device 602, a main memory 604 (e.g., read-only memory (ROM), flash memory, dynamic random access memory (DRAM) such as synchronous DRAM (SDRAM) or Rambus DRAM (RDRAM), etc.), a static memory 606 (e.g., flash memory, static random access memory (SRAM), etc.), and a data storage system 618, which communicate with each other via a bus 630.

Processing device 602 represents one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device 602 can also be one or more special-purpose processing devices such as an application specific integrated circuit (ASIC), a field programmable gate array (FPGA), a digital signal processor (DSP), network processor, or the like. The processing device 602 is configured to execute instructions 626 for performing the operations and steps discussed herein. The computer system 600 can further include a network interface device 608 to communicate over the network 620.

The data storage system 618 can include a machine-readable storage medium 624 (also known as a computer-readable medium) on which is stored one or more sets of instructions 626 or software embodying any one or more of the methodologies or functions described herein. The instructions 626 can also reside, completely or at least partially, within the main memory 604 and/or within the processing device 602 during execution thereof by the computer system 600, the main memory 604 and the processing device 602 also constituting machine-readable storage media. The machine-readable storage medium 624, data storage system 618, and/or main memory 604 can correspond to the memory subsystem 110 of FIG. 1.

In one embodiment, the instructions 626 include instructions to implement functionality corresponding to an operation tracker (e.g., the operation tracker 113 of FIG. 1). While the machine-readable storage medium 624 is shown in an example embodiment to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general-purpose computer selectively activated or reconfigured by a computer program stored in the computer. For example, a computer system or other data processing system, such as the controller 115, may carry out the computer-implemented methods 300-500 in response to its processor executing a computer program (e.g., a sequence of instructions) contained in a memory or other non-transitory machine-readable storage medium. Such a computer program can be stored in a computer readable storage medium, such as, but not limited to, any type of disk including floppy disks, optical disks, CD-ROMs, and magnetic-optical disks, read-only memories (ROMs), random access memories (RAMs), EPROMs, EEPROMs, magnetic or optical cards, or any type of media suitable for storing electronic instructions, each coupled to a computer system bus.

The algorithms and displays presented herein are not inherently related to any particular computer or other apparatus. Various general-purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some embodiments, a machine-readable (e.g., computer-readable) medium includes a machine (e.g., a computer) readable storage medium such as a read only memory (“ROM”), random access memory (“RAM”), magnetic disk storage media, optical storage media, flash memory components, etc.

In the foregoing specification, embodiments of the disclosure have been described with reference to specific example embodiments thereof. It will be evident that various modifications can be made thereto without departing from the broader spirit and scope of embodiments of the disclosure as set forth in the following claims. The specification and drawings are, accordingly, to be regarded in an illustrative sense rather than a restrictive sense.

What is claimed is:

1. A method comprising:
receiving a command for a deck of a memory, wherein the memory comprises a plurality of separately accessible decks partitioned from a physical block of the memory;
incrementing a read count for a deck of the plurality of separately accessible decks; and
responsive to determining that the read count for the deck of the plurality of separately accessible decks satisfies a read count threshold, triggering a read disturb scan of the deck.

2. The method of claim 1, wherein the command is one of a read command, an erase command, or a program verify command.

3. The method of claim 1, wherein the deck of the memory is an aggressor deck and another deck of the plurality of separately accessible decks other than the aggressor deck is a victim deck.

4. The method of claim 3, further comprising:
in response to determining that the victim deck is not erased, incrementing a read count for the victim deck.

5. The method of claim 3, further comprising:
in response to determining that the victim deck is erased and that a bias voltage is not applied to the aggressor deck, incrementing a read count for the victim deck.

6. The method of claim 3, wherein the command is an erase command, further comprising:
resetting a read count for the aggressor deck.

7. The method of claim 3, wherein the command is one of a read command or a program verify command, further comprising:
incrementing a read count for the aggressor deck.

8. A non-transitory computer-readable storage medium comprising instructions that, when executed by a processing device, cause the processing device to:
receive a command for a deck of a memory, wherein the memory comprises a plurality of separately accessible decks partitioned from a physical block of the memory;
increment a read count for a deck of the plurality of separately accessible decks; and
responsive to determining that the read count for the deck of the plurality of separately accessible decks satisfies a read count threshold, trigger a read disturb scan of the deck.

9. The non-transitory computer-readable storage medium of claim 8, wherein the command is one of a read command, an erase command, or a program verify command.

10. The non-transitory computer-readable storage medium of claim 8, wherein the deck of the memory is an aggressor deck and another deck of the plurality of separately accessible decks other than the aggressor deck is a victim deck.

11. The non-transitory computer-readable storage medium of claim 10, wherein the processing device is further to:
in response to determining that the victim deck is not erased, increment a read count for the victim deck.

12. The non-transitory computer-readable storage medium of claim 10, wherein the processing device is further to:
in response to determining that the victim deck is erased and that a bias voltage is not applied to the aggressor deck, increment a read count for the victim deck.

13. The non-transitory computer-readable storage medium of claim 10, wherein the command is an erase command, and wherein the processing device is further to:
reset a read count for the aggressor deck.

14. The non-transitory computer-readable storage medium of claim 10, wherein the command is one of a read command or a program verify command, and wherein the processing device is further to:
increment a read count for the aggressor deck.

15. A system comprising:
a plurality of memory devices; and
a processing device, operatively coupled with the plurality of memory devices, to:
receive a command for a deck of a memory, wherein the memory comprises a plurality of separately accessible decks partitioned from a physical block of the memory, and wherein the command is one of a read command, an erase command, or a program verify command;
increment a read count for a deck of the plurality of separately accessible decks; and
responsive to determining that the read count for the deck of the plurality of separately accessible decks satisfies a read count threshold, trigger a read disturb scan of the deck.

16. The system of claim 15, wherein the deck of the memory is an aggressor deck and another deck of the plurality of separately accessible decks other than the aggressor deck is a victim deck.

17. The system of claim 16, wherein the processing device is further to:
in response to determining that the victim deck is not erased, increment a read count for the victim deck.

18. The system of claim 16, wherein the processing device is further to:
in response to determining that the victim deck is erased and that a bias voltage is not applied to the aggressor deck, increment a read count for the victim deck.

19. The system of claim 16, wherein the command is an erase command, and wherein the processing device is further to:
reset a read count for the aggressor deck.

20. The system of claim 16, wherein the command is one of a read command or a program verify command, and wherein the processing device is further to:
increment a read count for the aggressor deck.
